(19) United States
(12) Patent Application Publication
(10) Pub. No.: US 2026/0180281 A1
(43) Pub. Date: Jun. 25, 2026

(54) SEMICONDUCTOR DEVICE WITH CARRIER HEAT SINK

(71) Applicant: Microchip Technology Inc., Chandler, AZ (US)

(72) Inventors: Bomy Chen, Newark, CA (US); Steve Nagel, Chandler, AZ (US)

(73) Assignee: Microchip Technology Inc., Chandler, AZ (US)

(21) Appl. No.: 19/203,263

(22) Filed: May 9, 2025

Related U.S. Application Data
(60) Provisional application No. 63/736,683, filed on Dec. 20, 2024.
(60) Provisional application No. 63/736,714, filed on Dec. 20, 2024.

(51) Int. Cl. H01S 5/024

(52) U.S. Cl. CPC H01S 5/02469

(57) ABSTRACT

Disclosed is a method of panel level packaging of one or more devices. The method comprises: providing a carrier with one or more cooling fins; placing a filler material between at least two of the one or more cooling fins; providing one or more components on the carrier; and removing the filler material. Also disclosed is a panel level packaged device, comprising one or more of a photonic integrated circuit and an electronic integrated circuit; and a carrier, having a mounting side onto which the photonic integrated circuit and/or the electronic integrated circuit are mounted. The carrier is configured with cooling protrusions on a side, opposite to the mounting side.

### CROSS-REFERENCE TO RELATED APPLICATIONS

This application claims priority to U.S. provisional application U.S. 63/736,683 filed on Dec. 20, 2024, and U.S. provisional application U.S. 63/736,714, filed on Dec. 20, 2024. The contents of the aforesaid patent applications are incorporated herein for all purposes.

### FIELD OF THE INVENTION

The present disclosure relates to thermal management of integrated semiconductor devices, such as optical or electrical components.

### BACKGROUND

Modern electronic devices comprise a multitude of integrated components. Recent developments increasingly add optical components in a in a co-packaged setup (co-packaged optics—CPO), for example to enable high speed data communications using optical transmitters or transceivers.

Some applications require high-power optical components, which may comprise lasers or other components that generate a significant amount of heat. Given the usual aim to miniaturize such integrated components, dissipating the generated heat may be challenging. In addition, other components (optical or electrical) in the vicinity of the high-power component may be negatively affected by the generated heat.

For example, where lasers are integrated in the vicinity of a photonic integrated circuit (PIC) and/or an electronic integrated circuit (EIC) in a CPO arrangement, degradation of performance of these circuits may be an issue.

A solution may be to move any high-power heat generating components ‘off-board’ and further away from other components of the package. This however increases its size and complexity.

### SUMMARY

There is a need for improved thermal dissipation in small IC packages, such as for example in a CPO integrated setup. The need is addressed by the subject matter of the independent claim(s). Embodiments of the invention are described in the dependent claims, the following description, and the drawings.

### BRIEF DESCRIPTION OF THE DRAWINGS

FIG. 1 illustrates an example carrier with example integrated semiconductor devices in a perspective view.

FIG. 2 illustrates a cross-section through an example carrier that has a fin-array as a heat sink.

FIG. 3 illustrates the example carrier of FIG. 2 with added filler material.

FIG. 4 illustrates the example carrier of FIG. 3 with added components.

FIG. 5 illustrates the example carrier of FIG. 4 with added cover material.

FIG. 6 illustrates the example integrated semiconductor device of FIG. 1, where the filler material has been removed.

FIG. 7 shows a top plan view of an example integrated semiconductor device.

FIG. 8 illustrates an example integrated semiconductor device in a cross-section after a portion of the metal carrier has been removed.

FIG. 9 illustrates the example integrated semiconductor device of FIG. 8 with additional packaging material.

### DESCRIPTION

The details of one or more embodiments are set forth in the accompanying drawings and the description below. Other features will be apparent from the description, drawings, and from the claims.

In the following description of embodiments of the invention, specific details are described in order to provide a thorough understanding of the invention. However, it will be apparent to one of ordinary skill in the art that the invention may be practiced without these specific details. In other instances, well-known features have not been described in detail to avoid unnecessarily complicating the instant description.

Some embodiments concern a method of panel level packaging of one or more devices, such as for example one or more semiconductor devices, optical devices, and co-packaged optics (CPO) devices comprising electrical components and optical components. In the context of the present discussion, the term ‘panel level packaging’ is understood according to the usual understanding in the art, namely a semiconductor packaging process using panels/carriers. Panel level packaging enables high-volume production with relatively low material waste.

In some embodiments, the method comprises providing a carrier with one or more cooling fins. The cooling fins may for example serve as a heat sink. Accordingly, instead of attaching a heat sink later to the finished product, the carrier is utilized as the heat sink in the present embodiments.

The carrier may be of any suitable type and format. For example, the carrier may be made of metal or a metallic (composite) material, such as, e.g., aluminum or steel. The carrier may be made by any suitable process. For example, the carrier with cooling fins may be made by molding/casting, machining (such as milling), or 3D (metal powder) printing. The carrier may in some embodiments be rectangular with a size of 515 mm×510 mm or 600 mm×600 mm. Alternatively and in some embodiments, the carrier may be round with a diameter of 12 inch or 24 inch. It is noted that, in the context of the present disclosure, the terms ‘carrier’ and ‘panel’ are used interchangeably.

The cooling fins may be of any suitable shape and size. In some embodiments, the fins have a length (perpendicular to the surface of the carrier) of 10-50 mm. In some embodiments, the cooling fins are formed integrally with the carrier, e.g., from the same material. In some embodiments, a plurality/multitude of cooling fins are provided.

In some embodiments, the method comprises placing a filler material between at least two of the one or more cooling fins. The filler material may be of any suitable type to provide mechanical stability to the carrier and the cooling fins for the further assembly process. For example, the filler material may comprise one or more of an oxide (e.g., SiO2) and a polymer. In some embodiments, the filler material is placed between the one or more cooling fins so that at least a substantial portion of a space between the cooling fins is provided with filler material. In some embodiments, the filler material is placed in at least 80% of the space between the cooling fins. In some embodiments, the entire space, i.e., close to or exactly 100%, between the cooling fins is filled with filler material.

In some embodiments, the method comprises providing one or more components on the carrier. The components may be of any suitable type, such as electrical/electronic semiconductor components (e.g., an electronic integrated circuit-EIC), mechanical components, or optical/optics components (e.g., a photonic integrated circuit-PIC). In some embodiments, the one or more components comprise one or more of a laser, a diode light source, and a photonic integrated circuit. In some embodiments, the one or more devices are co-packaged optics (CPO) devices, and the one or more components comprise at least one electrical/electronic component (electronic integrated circuit) and at least one optics/optical component (photonic integrated circuit). CPO arrangements allow for particularly small and efficient devices. In some embodiments, one or more components comprise a high-power component, such as a laser. In some embodiments, the method comprises forming a thermally conductive connection between the high-power component to the carrier such as by soldering or bonding.

The one or more components may be attached to the carrier with any suitable process. For example, the one or more components may be soldered to the carrier. In some embodiments, the one or more components are bonded to the carrier using, e.g., a thermally conductive material to allow an improved heat dissipation from the component to the carrier and the cooling fins during use. In some embodiments, a Thermal Interface Material (TIM) adhesive or gel is used to bond the one or more components to the carrier.

In some embodiments, the method comprises removing the filler material. This can be done in any suitable way, for example using a mechanical, chemical, and/or thermal removal process. For example, a wet etch process may be used. Once the filler material is removed, the cooling fins may be exposed to a cooling medium during use of the device, such as a cooling gas or a cooling fluid.

In some embodiments, the carrier is sheetlike, and the one or more cooling fins are provided on a first surface of the carrier. In some embodiments, the one or more components are provided on a second surface of the carrier. The carrier thus may have a ‘heat sink side’ and a ‘component side’. In some embodiments, the thickness of the base of the carrier may be between 0.1-3 mm.

In some embodiments, prior to removing the filler material, one or more optical waveguides are arranged on the carrier. These embodiments are particularly useful in case optical components are used on the device. The one or more optical waveguides may be bonded to the carrier or manufactured in place on the carrier, e.g., using refractive coatings for cladding and core of the waveguide. Since the filler material is present during the addition of the one or more optical waveguides, improved stability is given for the associated manufacturing operation. In some embodiments, the one or more optical waveguides are arranged on the component side of the carrier.

In some embodiments and prior to removing the filler material, a packaging material is arranged on at least parts of the carrier. The packaging material may be of any suitable type to partially or fully encase the one or more components. In some embodiments, a polymer is used as packaging material.

In some embodiments and prior to removing the filler material, a separating is conducted to obtain multiple separate devices. A separating—also referred to as dicing—refers to the separation of multiple devices that are formed on the same carrier. Separating prior to removing the filler material has the benefit of improved stability of the carrier during the separating process. Alternatively and in some embodiments, the separating is conducted after removing of the filler material. Doing so may increase efficiency as the filler material of multiple devices can be removed in a single operation.

In some embodiments, the method comprises forming at least one thermal break between a first component and a second component of the one or more components by at least partially removing the carrier between the first component and the second component. Forming the thermal break may be particularly beneficial to thermally isolate high-power components, such as lasers, diode light sources, transceivers, or power supplies, without limitation, from other components of the device.

In some embodiments, forming the at least one thermal break comprises partially removing the carrier between the first component and the second component at the intended location of the thermal break. Alternatively and in some embodiments, forming the at least one thermal break comprises completely removing the carrier at the intended location. In some embodiments, multiple thermal breaks are formed, where the carrier may be partially or fully removed.

Forming the at least one thermal break may be conducted in any suitable way. For example, a mechanical, chemical, or thermal at least partial removal of the carrier may be conducted. In some embodiments, at least partially removing the carrier comprises selectively applying a wet etch agent to a first surface of the carrier, on which first surface the one or more cooling fins are provided. In these embodiments, the carrier may be flipped upside-down, so that the one or more cooling fins face upwards for application of the wet etch agent. As will be easily apparent, the wet etch agent may be applied selectively, namely at the intended location(s) of the at least one thermal break. For example, a mask may be used to apply the wet etch agent at the intended location(s).

In some embodiments, selectively applying the wet etch agent comprises printing the wet etch agent. Using a printing process is particularly economic and allows a precise positioning of the at least one thermal break. In some embodiments, the wet etch agent is additionally used to at least partially remove the filler material, which may increase the efficiency of the process further.

Some embodiments relate to a panel level packaged device using the method described herein or one or more of the discussed embodiments.

Some embodiments relate to a panel level packaged device, comprising one or more of a photonic integrated circuit and an electronic integrated circuit, and a carrier. The carrier may have a mounting side onto which the photonic integrated circuit and/or the electronic integrated circuit are mounted and cooling protrusions on a heat sink side, opposite to the mounting side.

In some embodiments, the device comprises one or more of the photonic integrated circuits and one or more of the electronic integrated circuits in a co-packaged optics (CPO) arrangement.

In some embodiments, the device comprises one or more of lasers and diode light sources.

Some embodiments provide a (packaged) integrated semiconductor device with panel level packaging for one or more lasers, PICs (photonic integrated circuits) and EICs (electronic ICs) on a novel metal carrier that serves as a heat sink. The carrier may have cooling fins with a fill material (e.g., an oxide or a polymer) between them at least during the packaging process for structural stability. The fill material protects the heat sink fins during panel level processing and provides improved rigidity. The fill material may be removed, e.g., at the end of the packaging operation, to expose the cooling fins to the respective medium of the environment (e.g., gas, fluid) during use.

A heat sink thus is integrated into the packaging process as a carrier and may be directly or indirectly attached to heat generating elements (e.g., a laser) to provide efficient cooling where needed. The heat sink or parts thereof can optionally be removed in areas where it is not needed or wanted, i.e., providing a thermal break. For example, a thermal break may be provided in an area where the heat sink could provide a path for unwanted heat conduction between elements.

In some embodiments, a packaged IC device may be provided, where elements are in close vicinity to each other. A heat sink is provided where needed as part of the processing or packaging.

In some embodiments, a new panel design for panel level packaging is comprised of a patterned heat sink that is backfilled with for example oxide or polymer for stability during processing. When processing is complete, the backfill material may be wet etched away, leaving a heat sink. Accordingly and in some embodiments, a dual use panel/carrier is provided that can be used for panel level packaging and that also acts as a heat sink for components that need to be cooled. In some embodiments, portions of the heat sink may be removed between components to provide a thermal break.

In some embodiments, the setup is lowering cost by using the carrier as a heat sink and also connecting the heat sink to the die(s) compared with using a glass carrier that can be a barrier to heat transfer and where a separate device for heat dissipation would be arranged.

In some embodiments, the device is an integrated device with co-packaged optics, i.e., a CPO IC. In some embodiments, the device comprises at least a high-power device that generates a lot of heat, for example an APID or DPG. In some embodiments, the device is a high-speed communications device. In some embodiments, the device may be used for an FPGA, DCS, or CBU or wherever ultra high-speed communications are needed.

In some embodiments, a carrier for panel level packaging of one or more devices is provided. The carrier may for example be sheetlike and comprises a first surface and a second surface, wherein one or more cooling fins are provided on the first surface, and the second surface is configured to receive one or more components.

In some embodiments, a method is provided, where a metal carrier is attached to one or more integrated components in a package using panel level packaging. The metal carrier has a built-in heat sink. The heat sink comprises a filler that is removed after processing. In an optional processing operation, a thermal break (etch) is provided between components for thermal insulation. This may allow for a closer placement and/or a smaller footprint.

Reference will now be made to the drawings in which the various elements of embodiments will be given numerical designations and in which further embodiments will be discussed.

In the embodiments described herein, the described components of the embodiments each represent individual features that are to be considered independent of one another, in the combination as shown or described, and in combinations other than shown or described. In addition, the described embodiments can also be supplemented by features other than those described.

Specific references to components, process steps, operations, and other elements are not intended to be limiting. Further, it is understood that like parts bear the same or similar reference numerals when referring to alternate FIGS. The FIGS. are schematic and not necessarily to scale.

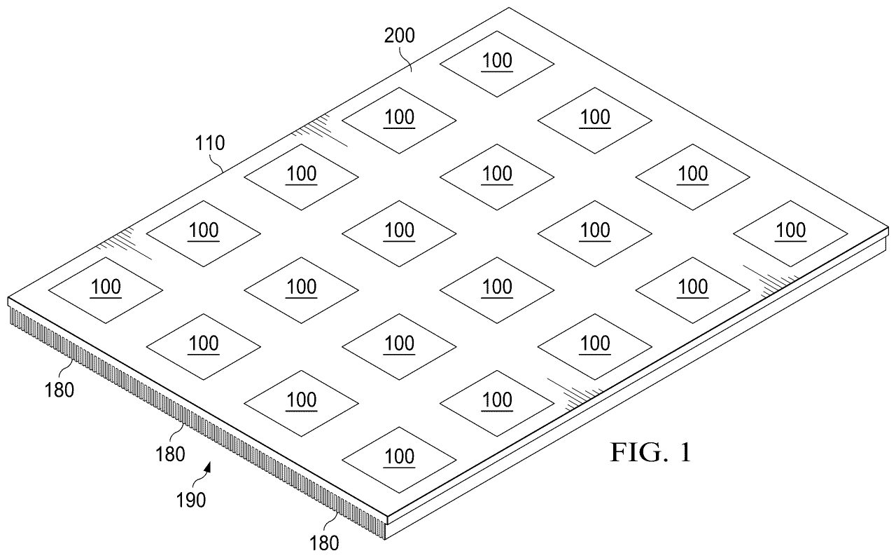

Embodiments relate to a method of panel level packaging (PLP) and a device, manufactured by PLP. The method begins by providing a carrier/panel 110, as shown in a perspective view in FIG. 1. The carrier 110 is rectangular with a size of 600 mm×600 mm and is made of metal (e.g., Al or SS). The thickness of the base of the carrier 110 is between 0.1-3 mm.

To manufacture the carrier 110, any suitable method of metal forming may be used, such as casting, milling, or 3D (metal powder) printing.

The carrier 110 is provided with a fin-array with a multitude of fins 180 on a first surface 190. The fins 180 serve as a heat sink for components 130, 140, 150 (not shown in FIG. 1) that are mounted to a second surface 200, also referred to herein as a mounting side. The fins 180 have a height of between 10-50 mm. As will be apparent to one skilled in the field of panel level packaging, the carrier 110 is used to manufacture a number of integrated semiconductor devices 100. The later positioning of these devices 100 on the carrier 110 is indicated in the schematic view of FIG. 1 by rectangular fields. Each corresponding field corresponds to a single device 100.

In the following, an example of a method of panel level packaging (PLP) will be discussed with reference to the manufacture of a single device 100. It will be appreciated however, that the method may be applied simultaneously to all devices 100 on the carrier 110. Corresponding to typical semiconductor manufacturing, a separation/dicing operation is conducted at the end of the process to provide multiple separate devices 100.

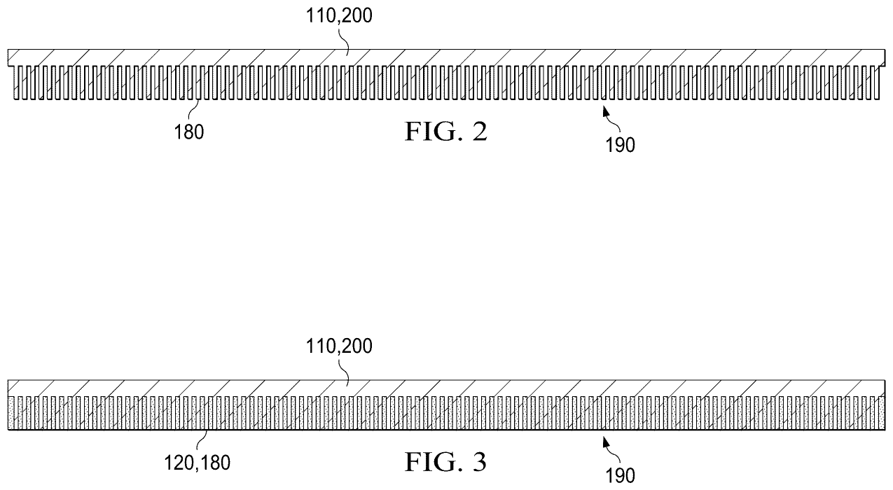

FIG. 2 shows a cross-sectional view of the example carrier 110 with cooling fins 180. According to the present embodiments, the method provides placing a filler material 120 into the spaces between the individual cooling fins 180. This is shown in the cross-sectional view of FIG. 3. The filler material 120 may for example be SiO2 or a polymer and is used to provide stability during the panel level packaging process as well as to protect the cooling fins 180 from mechanical damage using the processing.

In the case of SiO2 (glass) as filler material 120, a spin-on process may be used. In the case of a polymer as filler material 120, a liquid application, followed by a curing process (e.g., heat and/or UV light), may be used. In some embodiments, multiple curing operations are conducted (e.g., 2-3 rounds of curing) to obtain a polymeric filler 120 of sufficient density/stability.

As discussed in the preceding, a purpose of filler material 120 is to provide sufficient mechanical stability for the packaging operations and to avoid damage to the fins 180 of the carrier 110.

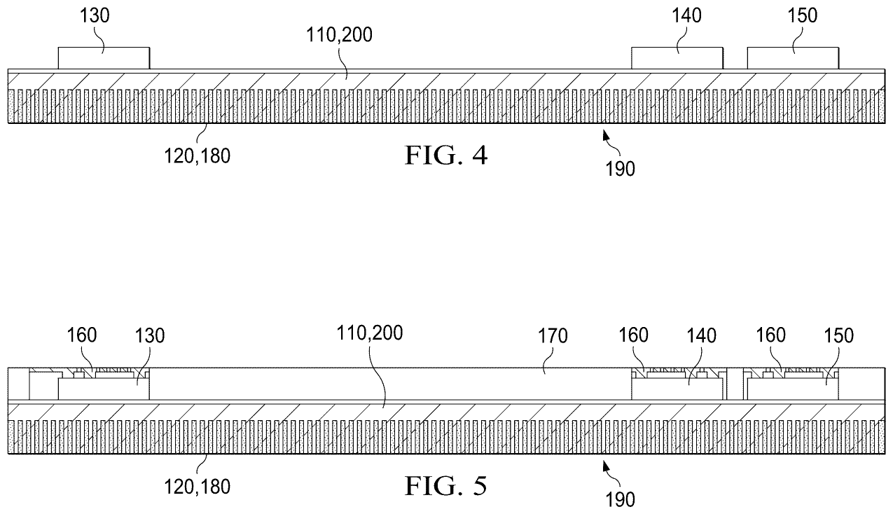

Once the filler material 120 is in place between the fins 180, one or more components, namely herein, a laser 130, a PIC 140 (photonic integrated circuits), and an EIC 150 (electronic ICs) are mounted to second surface 200 using a thermal interface material (TIM) to bond the components 130, 140, 150 to the carrier 110. This is shown in FIG. 4. It should be readily understood that the teachings herein are not limited to three components 130, 140, 150. Instead, any number of components may be attached to the carrier 110, depending on the respective application.

Once the components 130, 140, 150 are mounted to surface 200 of the carrier 110, electrical connections may be formed through application of an optional redistribution layer 160 (copper embedded in polymer) and various optional contacts (not shown) on each component 130, 140, 150. In addition, the laser 130 and PIC 140 may be connected using one or more waveguides (not shown). A covering material 170 may optionally be applied.

FIG. 5 shows the carrier 110 after the bonding of the components 130, 140, 150 and with redistribution layer 160 and cover material 170. One or more optional packaging operations, such as for example separation/dicing, may then be conducted.

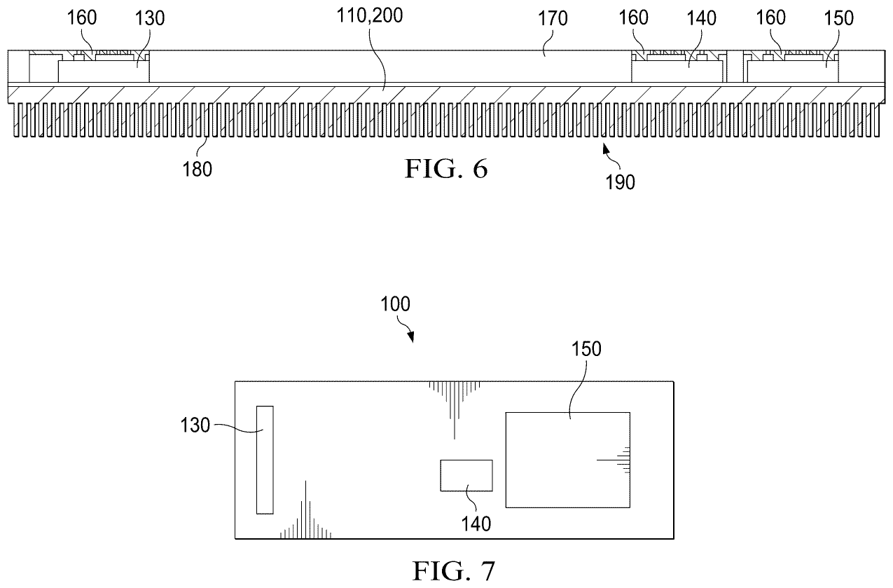

Once this is complete, the filler material 120 is removed to expose the fins 180 of the fin-array, as shown in FIG. 6. Removal of the filler material 120 may be conducted using any suitable process, depending on the respective filler material 120 used.

For an example SiO2 or polymeric filler material 120, a wet (etch) removal process may be used. Alternatively in case of a polymeric filler material 120, a thermal removal process may be used.

After the filler material 120 is removed and a separation/dicing is conducted, either before or after removal of the filler material 120, an integrated semiconductor device 100 is obtained, as shown in the plan view of FIG. 7.

In the present embodiments, the integrated semiconductor device 100 is of co-packaged setup (CPO), as it comprises electronic and photonic components, namely the laser 130, PIC 140 and EIC 150.

The integrated semiconductor device 100 may be further packaged, the package including but not limited to DIP (Dual-Inline Package), SOP (Small Outline Package), QFP (Quad Flat Package), TSOP (Thin Small Outline Package), PLCC (Plastic Leaded Chip Carrier), BGA (Ball Grid Array), WLP (Wafer Level Package), or another package type.

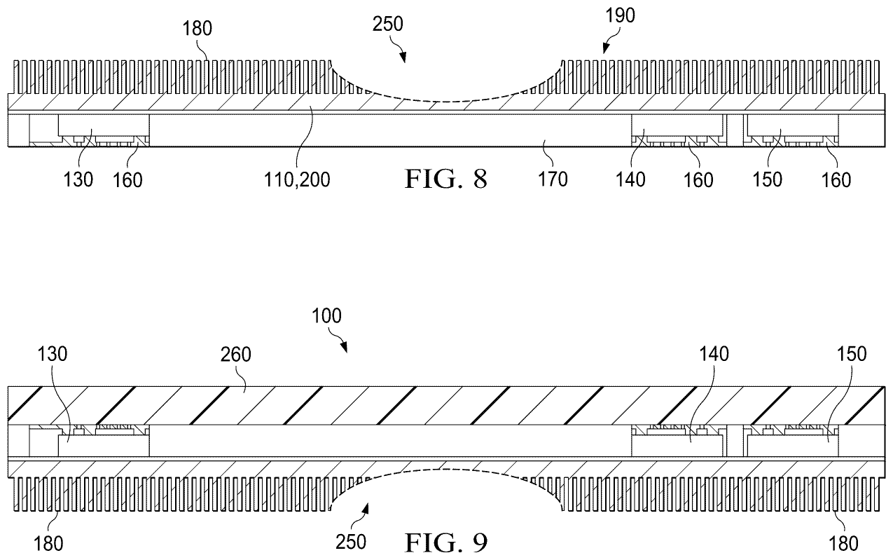

FIG. 8 shows an optional processing operation to obtain integrated semiconductor device 100, namely the introduction of one or more optional thermal breaks 250 into the carrier 110. This operation can be conducted either before or after removal of the filler material 120.

FIG. 8 illustrates the example carrier 110 in an upside-down cross-sectional view after a portion of the metal carrier 110 has been removed. The removal of the carrier 110 serves to reduce or prevent heat transfer from laser 130 to ICs 140, 150. As the inventors of the instant invention have determined, excessive heat from laser 130 may cause a degradation of performance in ICs 130, 140, depending on the physical distance between them.

To provide the thermal break 250, i.e., to partially remove the carrier 110, any suitable method may be used. For example, a flip panel 3D printed wet etch may be employed. Herein, an acid that can etch the material of carrier 110 is 3D printed in the desired area. For an example Al carrier, any fluid containing acid may be used that can etch aluminum, for example phosphoric acid.

In case the thermal breaks are introduced prior to removal of the filler material 120, a suitable wet etch agent may be used that can remove both, the filler 120 and the carrier 110 where desired. Although one thermal break is shown in the FIGS., it is noted that any number of thermal breaks may be provided, depending on the respective layout or requirements of the respective device.

FIG. 9 shows the completed example integrated semiconductor device 100 in a cross-sectional view with the discussed thermal break 250 and with an optional packaging material 260 on top.

The invention has been described in the preceding using various example embodiments. Other variations to the disclosed embodiments may be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor, device, or other unit may be arranged to fulfil the functions of several items recited in the claims. Likewise, multiple processors, devices, or other units may be arranged to fulfil the functions of several items recited in the claims.

The mere fact that certain measures are recited in mutually different dependent claims or embodiments does not indicate that a combination of these measures cannot be used to advantage. Any reference signs in the claims should not be construed as limiting the scope.

What is claimed is:

1. A method of panel level packaging of one or more devices, comprising:
providing a carrier with one or more cooling fins;
placing a filler material between at least two of the one or more cooling fins;
providing one or more components on the carrier; and
removing the filler material.

2. The method of claim 1, wherein the carrier is made of metal.

3. The method of claim 1, wherein the filler material comprises one or more of: an oxide and a polymer.

4. The method of claim 1, wherein the carrier is sheetlike, and the one or more cooling fins are provided on a first surface of the carrier, and the one or more components are provided on a second surface of the carrier.

5. The method of claim 1, wherein the filler material is placed between the one or more cooling fins so that at least a substantial portion of a space between the cooling fins is provided with filler material.

6. The method of claim 1, wherein prior to removing the filler material, one or more optical waveguides are arranged on the carrier.

7. The method of claim 1, wherein prior to removing the filler material, a packaging material is arranged on at least parts of the carrier.

8. The method of claim 1, wherein prior to removing the filler material, a separating is conducted to obtain multiple separate devices.

9. The method of claim 1, wherein the one or more devices are co-packaged optics devices, and the one or more components comprise at least one electronic component and at least one optical component.

10. The method of claim 1, wherein the one or more components comprise one or more of: a laser, a diode light source, and a photonic integrated circuit.

11. The method of claim 1, comprising forming at least one thermal break between a first component and a second component of the one or more components by at least partially removing the carrier between the first component and the second component.

12. The method of claim 11, wherein at least partially removing the carrier comprises selectively applying a wet etch agent to a first surface of the carrier, on which first surface the one or more cooling fins are provided.

13. The method of claim 12, wherein selectively applying the wet etch agent comprises printing the wet etch agent.

14. The method of claim 12, wherein the wet etch agent is additionally used to at least partially remove the filler material.

15. The method of claim 1, wherein the one or more components comprise a high-power component, the method comprising forming a thermally conductive connection between the high-power component and the carrier.

16. A panel level packaged device, manufactured with the method of claim 1.

17. A panel level packaged device, comprising:
one or more of a photonic integrated circuit and an electronic integrated circuit; and
a carrier, having a mounting side onto which one or more of the photonic integrated circuit and the electronic integrated circuit are mounted; wherein
the carrier is configured with cooling protrusions on a side, opposite to the mounting side.

18. The panel level packaged device of claim 17, comprising one or more of the photonic integrated circuit and one or more of the electronic integrated circuit in a co-packaged optics arrangement.

19. The panel level packaged device of claim 17, comprising one or more of: lasers and diode light sources.

20. A carrier for panel level packaging of one or more devices, wherein the carrier is sheetlike and comprises a first surface and a second surface, wherein one or more cooling fins are provided on the first surface, and the second surface is configured to receive one or more components.
